(19) United States
(12) Patent Application Publication
(10) Pub. No.: US 2011/0048521 A1
(43) Pub. Date: Mar. 3, 2011

(54) Thin Film Solar Cell Structure Having Light Absorbing Layer Made Of Chalcopyrite Powders

(76) Inventor: Wei-Lun Lu, Taichung County (TW)

(21) Appl. No.: 12/547,471

(22) Filed: Aug. 25, 2009

(51) Int. Cl. H01L 31/00

(52) U.S. Cl. 136/256

(57) ABSTRACT

A thin film solar cell structure having light absorbing layer made of chalcopyrite powders is provided. The thin film solar cell structure includes a substrate, a back electrode layer, a light absorbing layer, and a transparent conductive layer stacked one on another in that sequence. The light absorbing layer includes at least one layer of chalcopyrite powder stack structure constituted of a p-type chalcopyrite powder layer and an n-type chalcopyrite powder layer stacked on each other. The p-type chalcopyrite powder layer includes a plurality of single phase p-type chalcopyrite powders, and the n-type chalcopyrite powder layer includes a plurality of single phase n-type chalcopyrite powders. The p-type chalcopyrite powders and the n-type chalcopyrite powders are I-III-VI₂ compound materials. The group I element is Cu or a complex alloy compound thereof. The group III element is In, Ga, Al, or a complex alloy compound thereof. The group V1₂ element is S, Se, or a complex alloy compound thereof

### BACKGROUND OF THE INVENTION

1. Field of the Invention

The present invention relates generally to a thin film solar cell, and more particularly, to a thin film solar cell structure having a light absorbing layer made of chalcopyrite powders.

2. The Prior Arts

Thin film solar cells having the advantages of large area and simple processing have become a mainstream of the development of solar cells. Currently, among a variety of materials suitable for making the light absorbing layer of a thin film solar cell, I-III-VI₂ compounds are usually considered as the most promising materials. Typical I-III-VI₂ compounds include CuInSe₂ (CIS hereafter), and Cu(In,Ga)Se₂ (CIGS hereafter), which are ternary compounds derived from II-VI compounds. Such a ternary compound is featured with a crystallization phase of chalcopyrite structure, which is constituted of a stack of two hexagonal Zinc-blende structures. CIS or CIGS material is a direct band gap material having an energy band covering most of the solar spectrum. CIS or CIGS material also has a high coefficient of light absorption, a great radiation resistance, and optimal stability against heat and illumination. As such, CIS and CIGS materials can be selected as materials for making a light absorbing layer of a thin film solar cell having high efficiency and high stability.

In accordance with a conventional technology of preparing a I-III-VI₂ compound, the compound is usually obtained by performing a complicated and time-consuming processing with a plurality of ingredient metal powders. Taking CIS as an example, it is fabricated from a mixture of copper powder, indium powder, and selenium powder. Further, impurities are often introduced during the process of preparing the I-III-VI₂ compound, and the distribution of impurities greatly affects the quality of the I-III-VI₂ compound material, and may even further affect the conversion efficiency of the thin film solar cell using the compound. As such, in order to reduce the density of introduced impurities, raw materials having higher purities are often used, and the process of preparing the I-III-VI₂ compound is usually executed in a high vacuum environment. Unfortunately, such a high vacuum processing consumes very high expense.

Accordingly, a fast, convenient, and cheap process for preparing the I-III-VI₂ compound is desired to be developed. Moreover, the further improvement of the performance of the solar cell elements may be even more critical for developing the solar cells as a major renewable energy source. Therefore, although CIS or CIGS solar cells rank with the highest efficiency in the solar cells, the element performance thereof is still to be further improved.

### SUMMARY OF THE INVENTION

For providing a solution of the foregoing disadvantages of the conventional technologies of preparing CIS and CIGS compound materials, and further improving the photoelectric conversion efficiency of CIS or CIGS thin film solar cells, the present invention provides a thin film solar cell structure having a light absorbing layer made of a chalcopyrite powder. The light absorbing layer is constituted of a stack of a p-type chalcopyrite powder layer and an n-type chalcopyrite powder layer which contain single phase CIS or CIGS powders. Comparing with the conventional technologies, the fabrication process of preparing the single phase CIS or CIGS powder is faster and cheaper. The powder is prepared in nanometer scale, and therefore is further adapted for improving the photoelectric conversion efficiency.

The present invention provides a thin film solar cell structure. The thin film solar cell structure includes a substrate, a back electrode layer configured on the substrate, a light absorbing layer configured on the back electrode layer, and a transparent conductive layer configured on the light absorbing layer. The light absorbing layer includes at least one layer of chalcopyrite powder stack structure. The chalcopyrite powder stack structure is constituted of a p-type chalcopyrite powder layer and an n-type chalcopyrite powder layer stacked on each other. The p-type chalcopyrite powder layer includes a plurality of single phase p-type chalcopyrite powders, and the n-type chalcopyrite powder layer includes a plurality of single phase n-type chalcopyrite powders. For the purpose of achieving a more efficient photoelectric conversion, in the p-type chalcopyrite powder layer, it is preferred that n-type chalcopyrite powders within any hexagonal region encircled by p-type chalcopyrite powders are controlled to be less than 20% of the p-type chalcopyrite powders in the hexagonal region. Similarly, it is also preferred that in the n-type chalcopyrite powder layer, p-type chalcopyrite powders within any hexagonal region encircled by n-type chalcopyrite powders are controlled to be less than 20% of the n-type chalcopyrite powders in the hexagonal region. However, the percentage, i.e., 20% is given for illustration purpose only, and is not a restriction. Provides that a percentage between the p-type chalcopyrite powders and the n-type chalcopyrite powders in the aforementioned region does not adversely affect the photoelectric conversion, the percentage would have been taken as applicable.

The p-type chalcopyrite powders and the n-type chalcopyrite powders are I-III-VI₂ compound materials. The group I element is copper (Cu) or a complex alloy compound thereof The group III element is indium (In), gallium (Ga), aluminum (Al), or a complex alloy compound thereof The group V1₂ element is sulfur (S), selenium (Se), or a complex alloy compound thereof For example, the p-type chalcopyrite powders or the n-type chalcopyrite powders are CIS or CIGS material. Therefore, the chalcopyrite powder stack structure can be constituted of a p-type CIS powder layer and an n-type CIS powder layer stacked on each other, or a p-type CIGS powder layer and an n-type CIGS powder layer stacked on each other.

Further, the p-type CIS or n-type CIS powders are formed by mixing Se, Cu-contained compound, and In-contained compound with a metal chelating agent such as an ethylene-diamine solvent, and then processing the mixture under a high pressure and a temperature of 180° C. for 18 hours, and then processing the mixture with a washing agent for removing anions therefrom. Similarly, the p-type CIGS or n-type CIGS powders are formed by mixing Se, Cu-contained compound, In-contained compound, and Ga-contained compound with a metal chelating agent such as an ethylene-diamine solvent, and then processing the mixture under a high pressure and a temperature of 180° C. for 18 hours, and then processing the mixture with a washing agent for removing anions therefrom. The washing agent for example is deionized water, or an organic solvent. Finally, the powders are configured with spherical shape, line shape, wire shape, or multidimensional shape. The obtained p-type or n-type chalcopyrite powders have particle sizes ranging from 1 nm to 50 nm. When the obtained p-type or n-type chalcopyrite powders are wire shaped, the chalcopyrite powders are isotropically arranged or anisotropically arranged, in which an aspect ratio thereof ranges between 1 and 100.

On another hand, with respect to the thin film solar cell, the substrate is made of a material selected from the group consisting of glass, quartz, transparent plastic, and transparent flexible substrate. The back electrode layer is made of a metal material selected from the group consisting of aluminum (Al), nickel (Ni), gold (Au), silver (Ag), chromium (Cr), titanium (Ti), and palladium (Pd). The transparent conductive layer is made of a transparent conductive oxide (TCO) material selected from a group consisting of indium-tin-oxide (ITO), indium-zinc-oxide (IZO), aluminum-zinc-oxide (AZO), boron-zinc-oxide (BZO), gallium-zinc-oxide (GZO), and zinc oxide (ZnO).

The process of preparing the chalcopyrite powders according to the present invention is not required to be executed under a high vacuum environment, and the flow of the process, as well as the equipment used in the flow are simpler and more convenient than the conventional technologies. Further, the processing temperature of the present invention is not required to be very high, thus saving power consumption as well as the production cost. Furthermore, the CIS or CIGS powders of the present invention are configured in nanoscale, and therefore a printing technique or bias spraying technique can be employed for forming the light absorbing layer. In such a way, the complexity of the conventional vacuum processing (evaporation, sputtering selenylation) can be drastically lowered. On another hand, the nanoscale chalcopyrite powders are featured with an optimal quantum size effect, which facilitates to improve the light absorbing coefficient of the light absorbing layer. Moreover, the energy gap value can be adaptively controlled by adjusting the size distribution of the powders, thus further improving the photoelectric conversion efficiency.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a cross-sectional view of a thin film solar cell having a light absorbing layer made of chalcopyrite powders according to an embodiment of the present invention, in which the arrows represent incident light;

FIG. 2 is a schematic diagram illustrating a light absorbing layer constituted of a stack of a p-type chalcopyrite powder layer and an n-type chalcopyrite powder layer according to an embodiment of the present invention;

FIG. 3A is a schematic diagram illustrating a structure of the p-type chalcopyrite powder layer according to an embodiment of the present invention; and

FIG. 3B is a schematic diagram illustrating a structure of the n-type chalcopyrite powder layer according to an embodiment of the present invention.

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention.

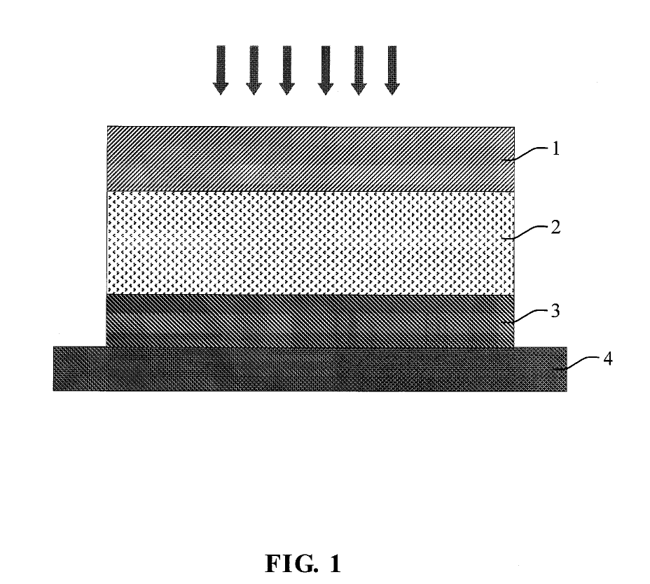

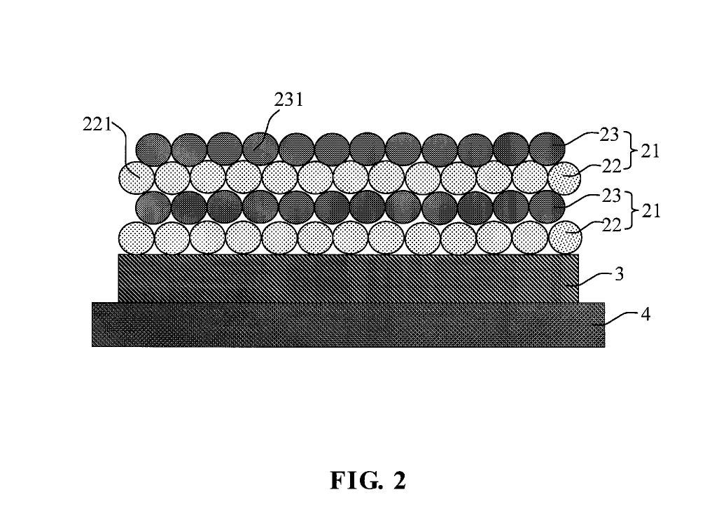

FIG. 1 is a cross-sectional view of a thin film solar cell having a light absorbing layer made of chalcopyrite powders according to an embodiment of the present invention, in which the arrows represent incident light. FIG. 2 is a schematic diagram illustrating a light absorbing layer constituted of a stack of a p-type chalcopyrite powder layer and an n-type chalcopyrite powder layer according to an embodiment of the present invention. Referring to FIGS. 1 and 2 together, there is shown a thin film solar cell structure having a light absorbing layer. The thin film solar cell structure includes a transparent conductive layer 1, a light absorbing layer 2, a back electrode layer 3, and a substrate 4 stacked one on another in that order. The incident light as shown by the arrows in FIG. 1 is directed to the transparent conductive layer 1. The light absorbing layer 2 includes at least one layer of chalcopyrite powder stack structure 21. The chalcopyrite powder stack structure 21 is constituted of a p-type chalcopyrite powder layer 22 and an n-type chalcopyrite powder layer 23 stacked on each other. The p-type chalcopyrite powder layer 22 includes a plurality of single phase p-type chalcopyrite powders 221, and the n-type chalcopyrite powder layer 23 includes a plurality of single phase n-type chalcopyrite powders 231. In the chalcopyrite powder stack structure 21, the p-type chalcopyrite powder layer 22 can be stacked on the n-type chalcopyrite powder layer 23, or alternatively the n-type chalcopyrite powder layer 23 is stacked on the p-type chalcopyrite powder layer 22, and therefore a p-n junction is formed between the p-type chalcopyrite powder layer 22 and the n-type chalcopyrite powder layer 23.

Further, with respect to the thin film solar cell structure, the transparent conductive layer 1 is made of a transparent conductive oxide (TCO) material selected from a group consisting of indium-tin-oxide (ITO), indium-zinc-oxide (IZO), aluminum-zinc-oxide (AZO), boron-zinc-oxide (BZO), gallium-zinc-oxide (GZO), and zinc oxide (ZnO). The back electrode layer 3 is made of a metal material selected from the group consisting of aluminum (Al), nickel (Ni), gold (Au), silver (Ag), chromium (Cr), titanium (Ti), and palladium (Pd). The substrate 4 is made of a material selected from the group consisting of glass, quartz, transparent plastic, and transparent flexible substrate.

The p-type chalcopyrite powders 221 and the n-type chalcopyrite powders 231 are I-III-VI₂ compound materials. The group I element is copper (Cu) or a complex alloy compound thereof. The group III element is indium (In), gallium (Ga), aluminum (Al), or a complex alloy compound thereof. The group VI₂ element is sulfur (S), selenium (Se), or a complex alloy compound thereof. For example, the p-type chalcopyrite powders 221 or the n-type chalcopyrite powders 231 are CIS or CIGS material. Therefore, the chalcopyrite powder stack structure 21 can be constituted of a p-type CIS powder layer and an n-type CIS powder layer stacked on each other, or a p-type CIGS powder layer and an n-type CIGS powder layer stacked on each other. One or more layers of such chalcopyrite powder stack structure 21 can be then taken as a light absorbing layer 2.

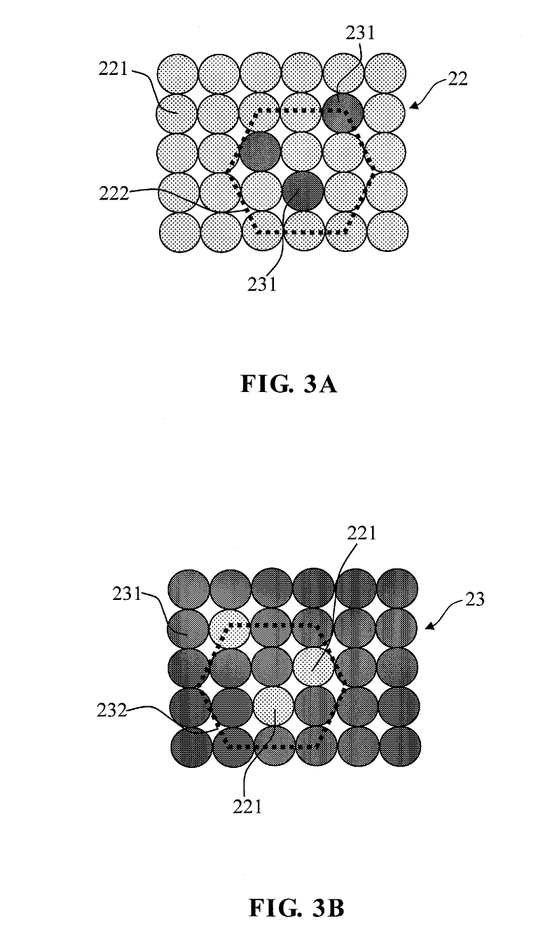

FIG. 3A is a schematic diagram illustrating a structure of the p-type chalcopyrite powder layer according to an embodiment of the present invention. FIG. 3B is a schematic diagram illustrating a structure of the n-type chalcopyrite powder layer according to an embodiment of the present invention. Referring to FIGS. 3A and 3B together, there are illustrated the p-type chalcopyrite powder layer 22 and the n-type chalcopyrite powder layer 23, respectively. For the purpose of allowing the chalcopyrite powder stack structure 21 to effectively performing the photoelectric conversion, the quantity of n-type chalcopyrite powders 231 in the p-type chalcopyrite powder layer 22 and the quantity of p-type chalcopyrite powders 221 in the p-type chalcopyrite powder layer 23 must be controlled. Preferably, in the p-type chalcopyrite powder layer 22, the n-type chalcopyrite powders 231 within any hexagonal region 222 encircled by p-type chalcopyrite powders 221 are controlled to be less than 20% of the p-type chalcopyrite powders 221 in the hexagonal region 222. Similarly, it is also preferred that in the n-type chalcopyrite powder layer 23, p-type chalcopyrite powders 221 within any hexagonal region 232 encircled by n-type chalcopyrite powders 231 are controlled to be less than 20% of the n-type chalcopyrite powders 231 in the hexagonal region 232. However, the percentage, i.e., 20% is given for illustration purpose only, and is not a restriction. Provides that a percentage between the p-type chalcopyrite powders 221 and the n-type chalcopyrite powders 231 in the aforementioned hexagonal region 222 or 232 does not adversely affect the photoelectric conversion, the percentage would have been taken as applicable.

Further, the chalcopyrite powders can be formed by mixing precursor salts with a metal chelating agent, and heating the mixture to a certain temperature for solving the precursor salts with the chelating agent to form a chelate complex containing anions and cations. Taking the CIS or CIGS powders as an example, when forming CIS powders, precursor salts including pure Se powders, Cu-contained compound, and In-contained compound are prepared, and when forming CIGS powders, precursor salts including pure Se powders, Cu-contained compound, In-contained compound and Ga-contained compound are prepared. The precursor salts are then mixed with an ethylene-diamine solvent, and the mixture is then processed under a high pressure and a temperature of 180° C. for 18 hours. Then, the mixture is processed with a washing agent for removing anions therefrom, thus obtaining single phase CIS or CIGS powders. The metal chelating agent for example is acetylacetone. However, it should be noted that the single phase CIS or CIGS powders are not restricted to be formed as disclosed above, and any other methods adapted for forming the single phase CIS or CIGS powders are applicable to be employed in the present invention.

The CIS or CIGS powders can be optionally formed into p-type or n-type CIS or CIGS powders by adjusting the ratio between the Cu-contained compound and the In-contained compound. For example, when the Cu/In mole ratio is greater than 1, p-type CIS or CIGS powders are obtained, and when the Cu/In mole ratio is smaller than 1, n-type CIS or CIGS powders are obtained.

In the process of forming the chalcopyrite powders, coordinate-covalent bond are configured between the chelating agent and free metal ions released from the precursor salts, so that the precursor salts are sufficiently dispersed. The chelating agent also absorbs heat released by the synthetic reaction, so as to improve the solubility of the precursor salts in the solvent, thus improving the completeness of the synthetic reaction. The washing agent for example can be deionized water, or an organic solvent. It should be noted that the selection of washing agent determines the structure of finally obtained powders. For example, when deionized water is selected serving as the washing agent, spherical shaped powders can be correspondingly obtained. Chalcopyrite powders having spherical shape are characterized with charges uniformly distributed on the spherical surfaces of the powders, while providing limited facilitation for the transmission of electron hole pairs in conductive polymer. When organic solvent, e.g., ethanol or isopropanol, is selected serving as the washing agent, line shaped, wire shaped, or multidimensional shaped powders can be correspondingly obtained. When the obtained p-type or n-type chalcopyrite powders are wire shaped, the chalcopyrite powders are isotropically arranged or anisotropically arranged, in which an aspect ratio thereof ranges between 1 and 100. Further, wire shaped powders are adapted for serving as carriers in conductive polymer for isotropically transmitting charges, thus providing facilitation for the transmission of electron hole pairs in the conductive polymer.

In the foregoing illustrated embodiments, the CIS or CIGS powders of the light absorbing layer 2 have particle sizes ranging from 1 nm to 50 nm. It should be noted that when the particle sizes decrease, the energy gap also correspondingly increases. In other words, the variation of the particle sizes of the CIS or CIGS powders is consistent with the quantum size effect. Therefore, the reaction time of the foregoing process can be controlled for adjusting the size distribution of the obtained CIS or CIGS powders, in which a longer reaction time usually corresponds to larger particle sizes of the powders, and vice versa. In addition, when the energy gap increases, the energy band also becomes wider. Such a widened energy band facilitates to improve the photoelectric conversion efficiency, thus enhancing the open circuit voltage. Comparing with the conventional technologies, the process of the present invention is executed under a relatively low temperature, i.e., 180° C., and therefore the metal ingredients are not likely to be oxidized under such a low temperature. Meanwhile, since the processing temperature of the present invention is not required to be very high, thus saving power consumption as well as the production cost. Furthermore, the CIS or CIGS powders of the present invention are configured in nanoscale, and therefore a printing technique or bias spraying technique can be employed for forming the light absorbing layer 2. In such a way, the complexity of the conventional vacuum processing (evaporation, sputtering selenylation) can be drastically lowered.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A thin film solar cell structure, comprising:
a substrate;
a back electrode layer configured on the substrate;
a light absorbing layer, configured on the back electrode layer, the light absorbing layer comprising at least one layer of chalcopyrite powder stacked structure, wherein the chalcopyrite powder stacked structure is constituted of a p-type chalcopyrite powder layer and an n-type chalcopyrite powder layer stacked on each other, wherein the p-type chalcopyrite powder layer comprises a plurality of single phase p-type chalcopyrite powders, and the n-type chalcopyrite powder layer comprises a plurality of single phase n-type chalcopyrite powders; and
a transparent conductive layer configured on the light absorbing layer.

2. The thin film solar cell structure according to claim 1, wherein in the p-type chalcopyrite powder layer, n-type chalcopyrite powders within any hexagonal region encircled by p-type chalcopyrite powders are less than 20% of the p-type chalcopyrite powders in the hexagonal region.

3. The thin film solar cell structure according to claim 1, wherein in the n-type chalcopyrite powder layer, p-type chalcopyrite powders within any hexagonal region encircled by n-type chalcopyrite powders are less than 20% of the n-type chalcopyrite powders in the hexagonal region.

4. The thin film solar cell structure according to claim 1, wherein the p-type chalcopyrite powders or the n-type chalcopyrite powders are I-III-VI₂ compound materials.

5. The thin film solar cell structure according to claim 4, wherein the group I element is copper (Cu) or a complex alloy compound thereof.

6. The thin film solar cell structure according to claim 4, wherein the group III element is indium (In), gallium (Ga), aluminum (Al), or a complex alloy compound thereof.

7. The thin film solar cell structure according to claim 4, wherein the group V1₂ element is sulfur (S), selenium (Se), or a complex alloy compound thereof.

8. The thin film solar cell structure according to claim 4, wherein the material of the p-type chalcopyrite powders or the n-type chalcopyrite powders is CuInSe₂ (CIS) or Cu(In,Ga)Se₂ (CIGS).

9. The thin film solar cell structure according to claim 4, wherein the p-type chalcopyrite powders or n-type chalcopyrite powders are formed by mixing Se, Cu-contained compound, and In-contained compound with a metal chelating agent, and then processing the mixture under a high pressure and a temperature of 180° C. for 18 hours, and then processing the mixture with a washing agent for removing anions therefrom.

10. The thin film solar cell structure according to claim 9, wherein the metal chelating agent is ethylene-diamine.

11. The thin film solar cell structure according to claim 9, wherein the washing agent is deionized water or an organic solvent.

12. The thin film solar cell structure according to claim 4, wherein the p-type chalcopyrite powders or n-type chalcopyrite powders are formed by mixing Se, Cu-contained compound, In-contained compound, and Ga-contained compound with a metal chelating agent, and then processing the mixture under a high pressure and a temperature of 180° C. for 18 hours, and then processing the mixture with a washing agent for removing anions therefrom.

13. The thin film solar cell structure according to claim 12, wherein the metal chelating agent is ethylene-diamine.

14. The thin film solar cell structure according to claim 12, wherein the washing agent is deionized water or an organic solvent.

15. The thin film solar cell structure according to claim 1, wherein the p-type chalcopyrite powders or n-type chalcopyrite powders are spherical shaped, line shaped, wire shaped, or multidimensional shaped.

16. The thin film solar cell structure according to claim 1, wherein the p-type chalcopyrite powders or n-type chalcopyrite powders have particle sizes ranging from 1 nm to 50 nm.

17. The thin film solar cell structure according to claim 1, wherein the p-type chalcopyrite powders or the n-type chalcopyrite powders are wire shaped.

18. The thin film solar cell structure according to claim 17, wherein an aspect ratio of the p-type chalcopyrite powders or the n-type chalcopyrite powders ranges between 1 and 100.

19. The thin film solar cell structure according to claim 17, wherein the p-type chalcopyrite powders or the n-type chalcopyrite powders are isotropically arranged or anisotropically arranged.

20. The thin film solar cell structure according to claim 1, wherein the transparent conductive layer is made of a transparent conductive oxide (TCO) material.

21. The thin film solar cell structure according to claim 20, wherein the TCO material is selected from a group consisting of indium-tin-oxide (ITO), indium-zinc-oxide (IZO), aluminum-zinc-oxide (AZO), boron-zinc-oxide (BZO), gallium-zinc-oxide (GZO), and zinc oxide (ZnO)

22. The thin film solar cell structure according to claim 1, wherein the substrate is made of a material selected from the group consisting of glass, quartz, transparent plastic, and transparent flexible substrate.
